(19) United States
(12) Patent Application Publication
(10) Pub. No.: US 2015/0143027 A1
(43) Pub. Date: May 21, 2015

(54) SOLID STATE DRIVE WITH RAID FUNCTIONS

(71) Applicant: Sage Microelectronics Corp., Saratoga, CA (US)

(72) Inventors: Jianjun Luo, Los Gatos, CA (US); Chuan-Jen Chris Tsu, Saratoga, CA (US)

(73) Assignee: Sage Microelectronics Corp., Saratoga, CA (US)

(21) Appl. No.: 14/099,770

(22) Filed: Dec. 6, 2013

Related U.S. Application Data
(63) Continuation-in-part of application No. 14/085,469, filed on Nov. 20, 2013.

(51) Int. Cl. G06F 3/06; G11C 14/00

(52) U.S. Cl. CPC G06F 3/0689; G06F 3/0688; G06F 3/0655; G06F 3/0619; G11C 14/009; G06F 2212/7208
USPC 711/103

(57) ABSTRACT

A single solid state drive (SSD) includes an SSD controller coupled to send and receive information to and from a host through an interface. The SSD controller includes an embedded RAID controller and a plurality of non-volatile memory modules (NVMs) coupled to the SSD controller. The SSD controller causes storage of the received information in the NVMs and sending of the information from the NVMs under the control of the embedded RAID controller.

### CROSS REFERENCE TO RELATED APPLICATIONS

This application is a continuation-in-part of U.S. patent application Ser. No. 14/085,469, filed on Nov. 20, 2013, by Jianjun Luo, and entitled, “REDUNDANT ARRAY OF INDEPENDENT MODULES”.

### FIELD OF THE INVENTION

Various embodiment of the invention relate generally to redundant array of independent disks (RAID) and particularly to RAID used for computer data storage.

### BACKGROUND

Redundant array of independent disks (RAID) is a storage technology that combines multiple disk drive components into a logical unit. Data is distributed across the drives in one of several ways called “RAID levels”, depending on the level of redundancy and performance required.

RAID is now used as an umbrella term for computer data storage schemes that can divide and replicate data among multiple physical drives. RAID is an example of storage virtualization and the array can be accessed by the operating system as one single drive. The different schemes or architectures are named by the word “RAID” followed by a key number (e.g. “RAID 0” or “RAID 1”). Each scheme provides a different balance between the key goals, such as reliability, availability, performance, and capacity. RAID levels that are greater than RAID 0 provide protection against unrecoverable (sector) read errors, as well as whole disk failure.

For example, RAID 6, which is for block-level striping with double distributed parity, provides fault tolerance up to two failed drives. This makes larger RAID groups more practical, especially for high-availability systems. This becomes increasingly important as large-capacity drives lengthen the time needed to recover from the failure of a single drive. A single drive failure results in reduced performance of the entire array until the failed drive has been replaced and the associated data rebuilt.

A RAID system is built up with multiple drive components, which are well-known as hard disks (HDD) and solid state drives (SSD). HDD is a motor driven disk with tape-inside as storage media. SSD is made up of flash memories. These types of disks all have interfaces such as SCSI, IDE, SATA, and PCI/PCIE.

However, the independent HDD and SSD consume much power and increase the size of a RAID system.

Accordingly, there is a need for improving the power consumption, cost and size of a RAID system.

### SUMMARY

Briefly, in an embodiment of the invention, a single solid state drive (SSD) includes an SSD controller coupled to send and receive information to and from a host through an interface. The SSD controller includes an embedded RAID controller and a plurality of non-volatile memory modules (NVMs) coupled to the SSD controller. The SSD controller causes storage of the received information in the NVMs and sending of the information from the NVMs under the control of the embedded RAID controller.

A further understanding of the nature and the advantages of particular embodiments disclosed herein may be realized by reference of the remaining portions of the specification and the attached drawings.

### BRIEF DESCRIPTION OF THE DRAWINGS

FIG. 1 shows a RAIM system, in accordance with an embodiment of the invention.

FIG. 2 shows a RAID controller module of the RAIM system of FIG. 1, in accordance with an embodiment of the invention.

FIGS. 3(a)-3(c) show pictures of SD cards, eMMC modules, and MMC cards, respectively. Each of these cards includes the RAIM system 2.

FIG. 4 shows a RAID controller, in accordance with another embodiment of the invention. This RAIM controller has RAID level-5 function.

FIG. 5 shows an example of the data stored in each of the modules 24 of FIG. 4.

FIG. 6 shows a RAID controller, in accordance with another embodiment of the invention, Having RAID Level 1 function.

FIG. 7 shows an example of the data stored in each of the independent SD modules 1 and 2 of FIG. 6.

FIG. 8 shows a system, in accordance with an embodiment of the invention.

FIG. 9 shows a system, in accordance with another embodiment of the invention.

FIG. 10 shows a system, in accordance with yet another embodiment of the invention.

### DETAILED DESCRIPTION OF EMBODIMENTS

Particular embodiments and methods of the invention disclose a Redundant Array of Independent Modules (RAIM), which works as a Redundant Array of Independent Disks (RAID). RAIM is built up by a group of independent modules, such as Secure Digital (SD)/Multi-Media Card (MMC)/embedded MMC (eMMC), instead of independent Hard Disk Drive (HDD) or Solid-State Drive (SSD) units. SD card, MMC and eMMC module, have less power consumption, are cost-effective and smaller in size.

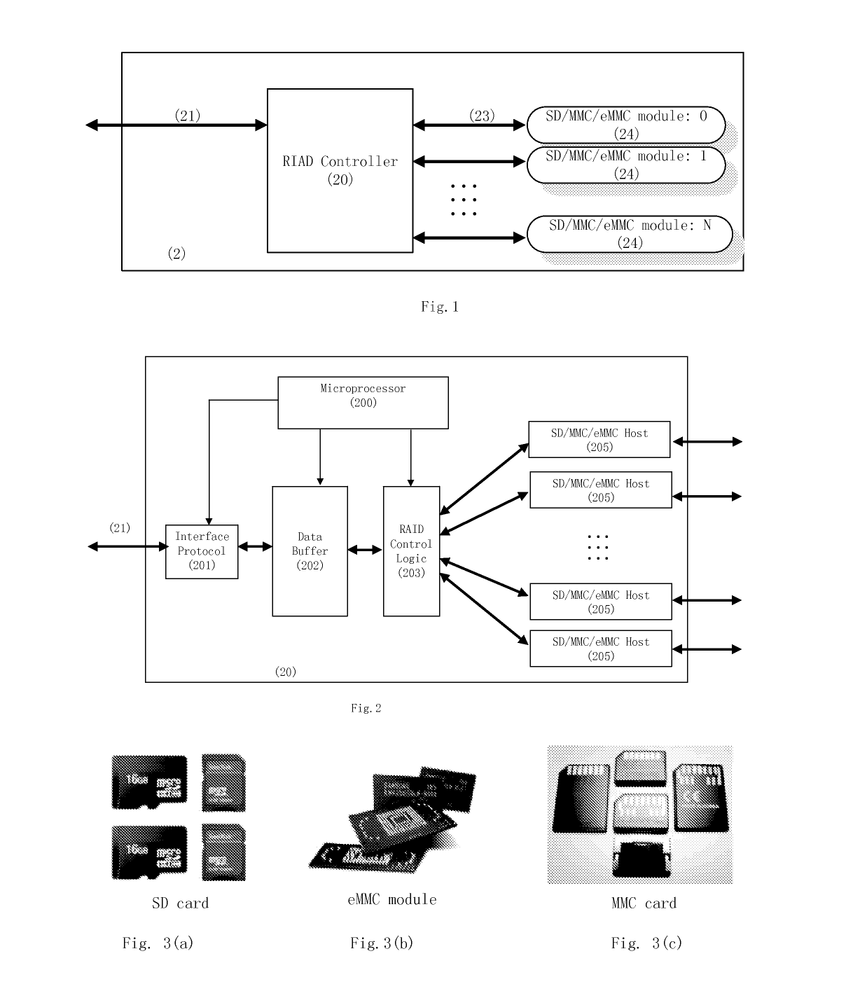

Referring now to FIG. 1, a RAIM system 2, is shown in accordance with an embodiment of the invention. ‘20’ in RAIM system 2 represents a particular mode of operation of the RAID system. While mode 2 is discussed herein, it is understood that any mode may be employed. The system 2 is shown to include a RAID controller 20, and modules 1-N, each being module 24 and “N” being an integer. The RAID controller 20 is shown coupled to each of the modules 24 through a bus 23. The RAID controller 20 is further shown coupled to a host (not shown) through an interface 21.

Each of the modules 24 is shown to be a Secure Digital (SD), Multi-Media Card (MMC), or embedded MMC (eMMC). In some embodiments, the bus 23 is a SD bus, a MMC bus, a eMMC bus, or a combination thereof depending on the type of module used as the modules 24. In some embodiments, the interface 21 is SCSI(Small Computer System Interface), IDE (Integrated Drive Electronics)/ATA (Advanced Technology Attachment)/Serial ATA(SATA), PCI(Peripheral Component Interconnect)/PCI Express (PCIE), SD, MMC, or eMMC.

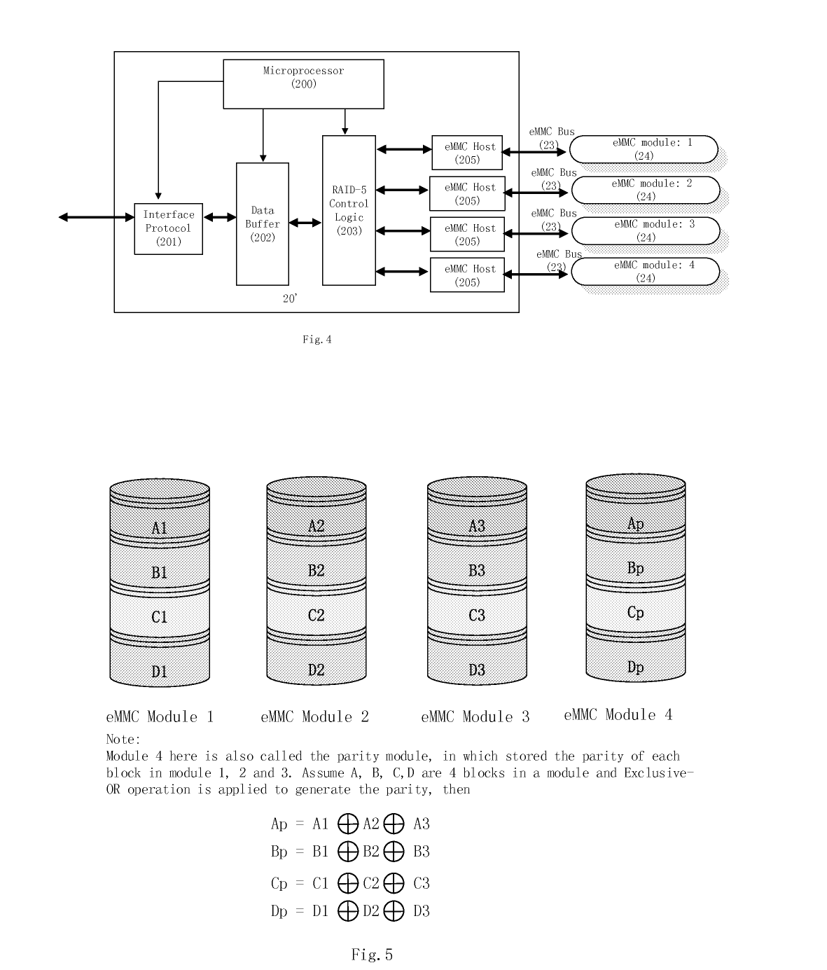

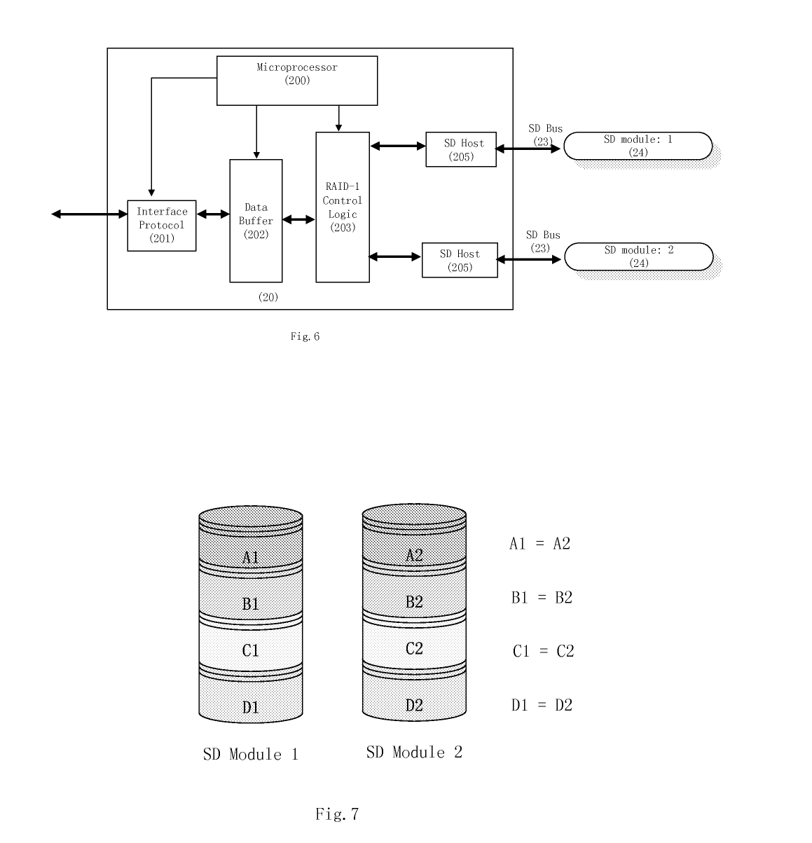

During operation, the RAID controller 20 of the RAIM system 2 receives or transmits information back and forth with the host 1. Information received is generally in the form of commands and data, the latter being for storage in the modules 24 through the RAID controller 20. The RAID controller 20 effectively manages the modules N and its functions are known to those in the art. For example in the case where the RAIM system 2 is a RAID Level 0 (RAIDO) system, the RAID controller 20 performs functions such as striping data between two or more disks, in the case of the embodiment of FIG. 1, the modules 24. In the case where the RAIM system 2 has RAID 1 (RAID Level 1) function embedded, the RAID controller 20 functions to minor data packages between two disks, such as the modules 24. This is further shown and discussed with respect to FIGS. 6 and 7. While discussed herein, it is contemplated that the RAID controller 20 performs many other functions depending on the RAIM system in which it is being employed.

The system 2 is a storage device with RAID function, but it is not like a RAID system which is built up by independent disks such as HDD or SSD. The system is built up by an array of independent modules. Those modules of the modules 24 that are made of SD, are compliant with the SD Association standard. And those modules of the modules 24 that are MMC or eMMC are compliant with the MMC Association and JEDEC Organization. In all of these cases, the modules 24 replace traditional HDD and SSDs. Using SD, MMC or eMMC modules 24 in conjunction with the controller 20 has advantages in cost, size and power consumption.

The modules 24 are grouped together by the RAID controller 20 thereby reducing the size and power consumption of the RAIM system 2 and therefore cost-effective. For example, in FIGS. 4 and 5, the RAID controller 20 has RAID Level 5 (RAID 5) function, therefore, the data packets from the modules are grouped in sequence of A1, A2, A3, B1, B2, B3, . . . in sector size (1 sector=512 byte) while the data packet from the module 4 is treated as the parity sector, which is used to recover any corrupt data packet among the modules. Of course, the data packet size can be in sector size (512 byte), also in other size like 1K byte, 2K byte or more. The modules 24 collectively act (or regarded) as a single disk if compared with a RAID system, which causes the RAIM system 2 to have high reliability. The modules 24 can be regarded as a virtual independent disk (VID) by comparing a RAIM and RAID systems. For example, a maintenance engineer can hot-plug out one life-time exhausted eMMC or SD module and replace it with a brand new module because data can be automatically recovered by an inside RAID mechanism. For example, assume module 2 in FIG. 6 is plug-out and replaced with a brand-new SD module, the controller 20 can copy all the information in the rest module (module 1) into this brand-new module, and finally recover the whole RAIM system to the status before module 2 is plug-out. This kind of single disk can also be used to build a second level RAID with high efficiency.

FIG. 2 shows further details of the RAID controller 20, in accordance with an embodiment of the invention. The RAID controller 20 is shown to include an Intellectual Protocol (IP) 201, a microprocessor 200, a data buffer 202, a RAID control logic 203, and N number of SD/MMC/eMMC hosts 205. The IP 201 is shown to be coupled to the bus 21 and the data buffer 202 and responsive to information from the microprocessor 20. The data buffer 202 is also shown coupled to receive information from the microprocessor 200 and is further shown coupled to the RAID control logic 203. The RAID control logic 203 is shown coupled to each of the hosts 205. Each of the hosts 205 communicates with the modules 24 (not shown in FIG. 2) through the bus 23.

The microprocessor 200, through execution of software, instructs the IP 201 to receive or send information to the host 1 and the data buffer 202. The microprocessor 200 instructs the transfer of information from the IP 201 and the data buffer 202 and the data buffer 202 temporarily stores information to be written to or read from the modules 24. The RAID control logic 203, which is coupled to the data buffer 202, under the direction of the microprocessor 200, arbitrates data between the data buffer 202 and the hosts 205. Each of the hosts 205 issues commands to its connected module 24 and read status from its connected module 24 as well as transfer data to and from its connect module 24 via bus 23. From the view of module side, the host 205 takes the role of SD or MMC/eMMC card reader.

FIGS. 3(a)-3(c) show pictures of SD cards, eMMC modules, and MMC cards, respectively. Each of these cards can be used in the RAIM system 2.

FIG. 4 shows another embodiment of the RAID controller. The RAID controller 20′ of FIG. 4 analogous to that of FIG. 2 except that in FIG. 4, the RAID control logic 203′ is a RAID Level 5 type of control logic.

FIG. 5 shows an example of the data stored in each of the modules 24 of FIG. 4. For the sake of clarity, the modules 24 are labelled as modules 24-1, 24-2, 24-3, and 24-4. Data in the modules 24-1 through 24-3 is in the form of blocks. The module 24-4 is also referred to as a parity module because it stores the parity of each block in the modules 24-1, 24-2, and 24-3. In the embodiment of FIG. 5, blocks 502-508, four blocks, are stored in the modules 24-1 through 24-3. Module 24-4 stores the parity for each of these blocks. For example, the block 502 is made of A1, stored in module 24-1, A2, stored in module 24-2, and A3, stored in module 24-3. A1-A3 comprise the block 502. One form of parity is exclusive ORing (a logic operation well known in the art) A1, A2, and A3 and storing the result in Ap of the module 24-4. Similarly, B1, B2, and B3, which are stored in modules 24-1, 24-2, and 24-3, respectively, are exclusive ORed with the result Bp stored in the module 24-4. B1-B3 comprising another block, the block 504. The same applies to blocks 506 and 508.

FIG. 6 shows another embodiment of the RAID controller. The embodiment of FIG. 6 shows a RAID controller 20″, which is analogous to the RAID controller 20′ except that the RAID control logic 203″, which is a part of the RAID controller 20″, is different than the RAID control logic 203′. The RAID control logic 203′ is a RAID Level 1 type causing the hosts 205 to be coupled to the SD modules 1 and 2 of the modules 24, through (SD) busses 23.

FIG. 7 shows an example of the data stored in each of the SD modules 1 and 2 of FIG. 6. In the RAIM system of which the RAID control logic 20″ is a part, the content of the blocks of data are mirrored. For example, the SD module 1, includes A1, which is a block or part of a block and the same holds true for A2 of SD module 2 but because of RAID 1, A1 is the same as A2. Similarly, B1 of SD module 1 is the same as B2 of SD module 2 and so on.

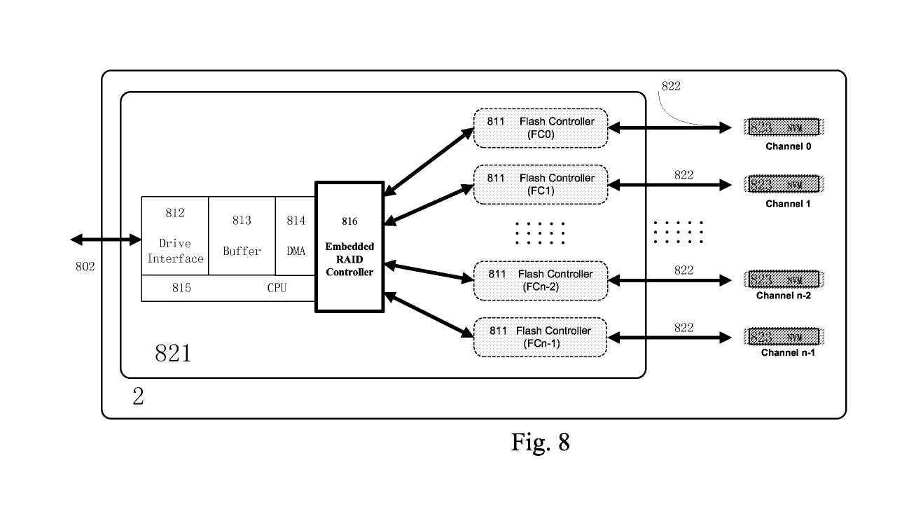

FIG. 8 shows a system, in accordance with an embodiment of the invention. The system is a single SSD 2 in communication with a host (not shown) through an interface 802. The interface 802 is analogous to the interface 21. The SSD 2 may be coupled to an intermediary device that is coupled to the host. The SSD 2 is further shown coupled to ‘n’ number of non-volatile memory modules (NVMs) 823 through NVM busses 822. That is, each of the NVMs 823 is coupled to the SSD 2 through a distinct NVM bus of the NVM busses 822. ‘N’ is an integer. The NVMs 823 are also referred to herein as channels 0 through n-1.

The SSD 2 is shown to include SSD controller 821. The SSD controller 821 is shown to include a CPU 815, a drive interface 812, a buffer 813, a direct memory access (DMA) 814, an embedded RAID controller 816, and n-1 non-volatile controller modules 811. The modules 811 are shown coupled to the NVMs 823 through the busses 822. That is, each of the modules 811 is shown coupled to a distinct NVM of the NVMs 823 through a distinct bus of the busses 822.

The controller 816 is embedded in the SSD 2 and has the capability to perform various RAID functions. In some embodiments, the controller 816 is a single integrated circuit chip or a circuit board with multiple integrated circuit chips. The controller 816 supports one or multiple levels (modes) of RAID0, 1, 2, 3, 4, 5, 6 or a combination of these modes. The controller 816 distributes data to the non-volatile memory controller modules 811 (in a writing operation) and receives data from non-volatile memory controller modules 811 (in a read operation) by a rule or operation defined by the RAID level.

There are at least one non-volatile memory controller module 811 in the RAID controller 821 but typically, there are more than one modules 811. The non-volatile memory controller module 811 manages a group of non-volatile memory chips. It may have some sub-modules or functions including wear-leveling algorithms, Error Correction Code (ECC), scrambling engine. Non-volatile memory modules (NVMs) 823 is computer memory that can get back stored information even when not powered. The NVMs 823 of the RAID controller 821 are typically NAND flash memory, but can also be NOR flash memory or phase change memory (PCM), Ferroelectric RAM (F-RAM), or Magnetoresistive RAM (MRAM).

There is at least one non-volatile memory bus 822, and typically more than one is employed. The non-volatile memory controller modules 811 access data via the bus 822.

In operation, under the control of the CPU 815, information, such as command and data, is received by the drive interface 812, through the interface 802. The information is temporarily saved in the buffer 813. The DMA (Direct Memory Access) 814, under the direction of the controller 816, transfers the data between SATA internal buffer memory 813 and the RAID controller logic 816, and distributed to the controllers 811, which ultimately save the data that is intended to be saved by the host, in the NVMs 823.

The controller 816 is configurable to support various RAID levels. The CPU 815 configures the controller 816 to a specific level.

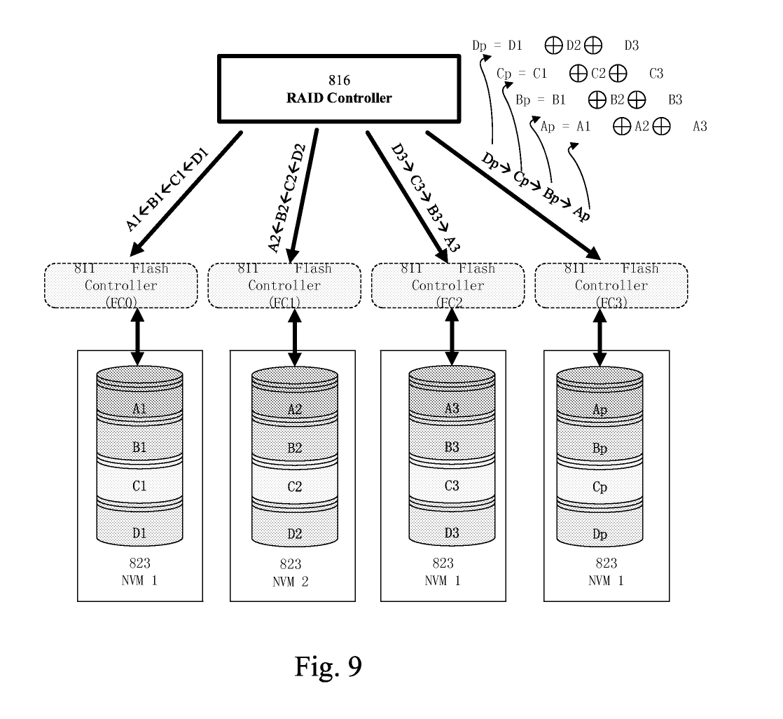

FIG. 9 shows a system, in accordance with another embodiment of the invention. In the embodiment of FIG. 9, the controller 816 is shown configured as RAID level 5. The controller 216 distributes the data to three NVMs 823 through the non-volatile controllers 811. A fourth NVM of the NVMs 823 received parity from the controller 816, similar to that which is shown in and described in FIG. 5. In FIG. 9, the controller 816, non-volatile controllers 811, and NVMs 823 are the same as their counterparts in FIG. 8.

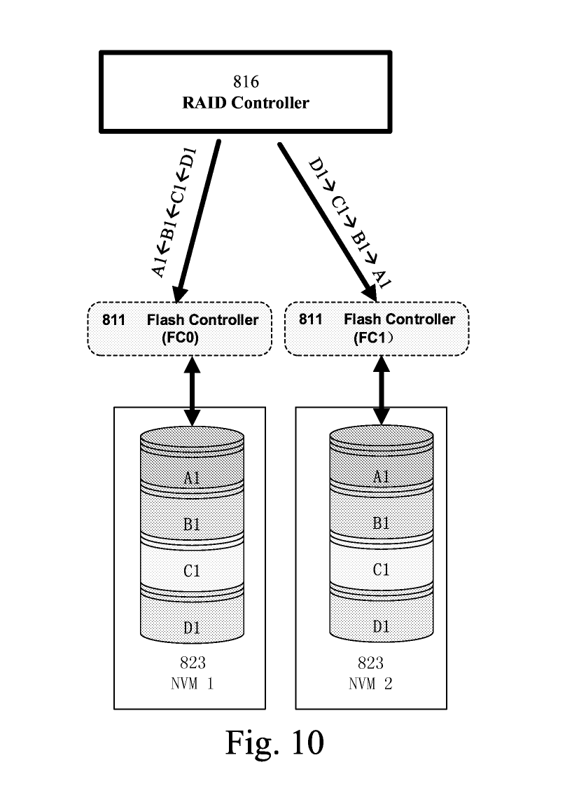

FIG. 10 shows a system, in accordance with yet another embodiment of the invention. Another example of the controller 816 configured with another RAID level, RAID level 1. FIG. 10 shows the NVMs 823 to be two NVMs, NVM 1 and NVM 2. The controller 816 distributes data to the NVM 1 while mirroring the data in NVM 2.

Although the description has been described with respect to particular embodiments thereof, these particular embodiments are merely illustrative, and not restrictive.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

Thus, while particular embodiments have been described herein, latitudes of modification, various changes, and substitutions are intended in the foregoing disclosures, and it will be appreciated that in some instances some features of particular embodiments will be employed without a corresponding use of other features without departing from the scope and spirit as set forth. Therefore, many modifications may be made to adapt a particular situation or material to the essential scope and spirit.

What we claim is:

1. A single solid state drive (SSD) comprising:
an SSD controller coupled to send and receive information to and from a host through an interface, the SSD controller including an embedded RAID controller; and
a plurality of non-volatile memory modules (NVMs) coupled to the SSD controller, the SSD controller causing storage of the received information in the NVMs and sending of the information from the NVMs under the control of the embedded RAID controller.

2. The single SSD of claim 1, wherein the plurality of modules are Secure Digital (SD).

3. The single SSD of claim 1, wherein the plurality of modules are Multi-Media Card (MMC).

4. The single SSD of claim 1, wherein the plurality of modules are embedded MMC (eMMC).

5. The single SSD of claim 1, wherein the plurality of SD modules are coupled to the RAID controller through a SD bus.

6. The single SSD of claim 1, wherein the plurality of MMC modules is coupled to the RAID controller through a MMC bus.

7. The single SSD of claim 1, wherein the plurality of eMMC modules is coupled to the RAID controller through an eMMC bus.

8. The single SSD of claim 1, wherein the interface is SCSI (Small Computer System Interface), IDE (Integrated Drive Electronics)/ATA (Advanced Technology Attachment)/Serial ATA(SATA), PCI (Peripheral Component Interconnect)/PCI Express (PCIE), SD, MMC, or eMMC.

9. The single SSD of claim 1, wherein the RAID controller functions in one of a plurality of modes (levels), for example RAID Level 1, RAID Level 5, RAID Level 6.

10. The single SSD of claim 1, wherein the RAID controller includes a RAID control logic that is coupled to the plurality of modules.

11. The single SSD of claim 10, wherein the RAID control logic that is coupled to the plurality of modules through SD host or MMC/eMMC host.

12. The single SSD of claim 1, wherein the NVMs are NAND flash or NOR flash.

13. The single SSD of claim 1, wherein the NVMs are hase change memory (PCM), Ferroelectric RAM (F-RAM), or Magnetoresistive RAM (MRAM).
